(19) United States
(12) Patent Application Publication
(10) Pub. No.: US 2014/0209140 A1
(43) Pub. Date: Jul. 31, 2014

(54) STACKED THERMOELECTRIC CONVERSION MODULE

(71) Applicants: Ryoji Funahashi, Ikeda-shi (JP); Saori Urata, Ikeda-shi (JP); Tetsuo Nomura, Ikeda-shi (JP)

(72) Inventors: Ryoji Funahashi, Ikeda-shi (JP); Saori Urata, Ikeda-shi (JP); Tetsuo Nomura, Ikeda-shi (JP)

(73) Assignees: TES NewEnergy Co., Ikeda-shi, Osaka (JP); NATIONAL INSTITUTE OF ADVANCED INDUSTRIAL SCIENCE AND TECHNOLOGY, Tokyo (JP)

(21) Appl. No.: 14/130,590

(22) PCT Filed: Jul. 18, 2012
(86) PCT No.: PCT/JP2012/068175

§ 371 Date: Jan. 2, 2014

(30) Foreign Application Priority Data
Jul. 19, 2011 (JP) 2011-158067

(51) Int. Cl. H01L 35/32

(52) U.S. Cl. CPC H01L 35/32
USPC 136/205

(57) ABSTRACT

A stacked thermoelectric conversion module has a structure in which the following are stacked: a module for use in a high-temperature portion which is a thermoelectric conversion module in which a metal oxide is used as each thermoelectric conversion material or a thermoelectric conversion module in which a silicon-based alloy is used as each thermoelectric conversion material; and a module for use in a low-temperature portion which is a thermoelectric conversion module in which a bismuth-tellurium-based alloy is used as each thermoelectric conversion material. The stacked thermoelectric conversion module disposes a flexible heat-transfer material and, if necessary, a metal sheet between the module for use in a high-temperature portion and the module for use in a low-temperature portion. Also, the stacked thermoelectric conversion module disposes a cooling member on the cooling surface side of the module and a flexible heat-transfer material.

### TECHNICAL FIELD

The present invention relates to a stacked thermoelectric conversion module.

### BACKGROUND ART

Waste heat exhausted from industrial furnaces, waste incinerators, or automobiles exhibits temperatures as high as 400° C. or more. Thermoelectric power generation, in which waste heat is used to generate electric power by electromotive force based on the Seebeck effect, is expected to help solve energy problems. The conversion efficiency of previously developed thermoelectric power generation materials largely depends on the temperature, but there have been no materials showing good performance in wide temperature ranges, such as 100° C. or less on the low temperature side and 400° C. or more on the high temperature side. Further, except for certain materials, such as oxide-based thermoelectric materials, most of the materials are oxidized in air around at 300 to 400° C.; thus, the temperature range in which one type of thermoelectric power generation material can be used is limited. Therefore, to use thermoelectric power generation materials in suitable temperature ranges, a stacked module has been developed in which constituent modules formed of different thermoelectric power generation materials are respectively disposed at the high temperature side and the low temperature side (Non Patent Literature 1). In particular, a stacked thermoelectric module in which an oxide-type thermoelectric module having high durability even in air is used at the high temperature side, and a bismuth-tellurium-type thermoelectric module exhibiting a high conversion efficiency at room temperature to 200° C. is used at the low temperature side can generate electric power using waste heat in a wide temperature range of 300 to 1100° C.

However, when a plurality of thermoelectric conversion modules are stacked, and such a stacked module is placed between a heat-collecting member and a cooling member, the surface roughness of each module or deformation due to thermal stress generates a gap (void) between the modules or between the thermoelectric conversion module and the cooling member. The thermal resistivity of air is a large value exceeding 40 mK (meter kelvin)/W, and the gap prevents heat flow into the thermoelectric module, which is one of the main reasons for drops in thermoelectric power generating efficiency. The problem is particularly significant in a stacked thermoelectric unit, which is usable in a wide temperature range, that includes a thermoelectric conversion module using as each thermoelectric conversion material a metal oxide or a silicon-based alloy and a thermoelectric conversion module using a bismuth-tellurium-based alloy as each thermoelectric conversion material.

### CITATION LIST

### Non-Patent Literature

NPL 1: Takenobu KAJIKAWA, Thermoelectric Power Generation Forum Proceedings, pp. 5 to 8 (2005).

### SUMMARY OF INVENTION

### Technical Problem

The present invention was made in view of the status of the prior art, and a main object of the present invention is to provide a novel stacked thermoelectric conversion module having a structure in which a plurality of thermoelectric conversion modules are stacked, wherein factors resulting in drops in thermoelectric power generating efficiency are eliminated, enabling efficient thermoelectric power generation.

### Solution to Problem

The present inventors conducted extensive research to achieve the above object. As a result, they found that when a thermoelectric conversion module using a metal oxide or a silicon-based alloy as each thermoelectric conversion material that exhibits excellent thermoelectric conversion performance at high temperatures is used in combination with a thermoelectric conversion module using a bismuth-tellurium-based alloy as each thermoelectric conversion material that exhibits excellent thermoelectric conversion performance at a relatively low-temperature atmosphere, and these modules are stacked, a stacked module exhibiting excellent thermoelectric conversion performance in a wide temperature range can be obtained. The present inventors also found that providing a flexible heat-transfer material and optionally a metal plate between the modules can fill the gap between the module for use in a high-temperature portion and the module for use in a low-temperature portion to improve heat transfer performance, and prevent breakage due to deformation, thus providing a thermoelectric conversion module with excellent durability and thermoelectric conversion performance. Further, the present inventors found that providing a flexible heat-transfer material between the module for use in a low-temperature portion and the cooling member can also improve heat transfer performance, thus providing a thermoelectric conversion module with excellent thermoelectric conversion performance. The present invention was accomplished as a result of further research based on these findings.

More specifically, the present invention provides the stacked thermoelectric conversion modules described below.

Item 1. A stacked thermoelectric conversion module having a structure wherein a module for use in a high-temperature portion and a module for use in a low-temperature portion are stacked:

the module for use in a high-temperature portion being a thermoelectric conversion module comprising a metal oxide as each thermoelectric conversion material or a thermoelectric conversion module comprising a silicon-based alloy as each thermoelectric conversion material;

the module for use in a low-temperature portion being a thermoelectric conversion module comprising a bismuth-tellurium-based alloy as each thermoelectric conversion material; and

a flexible heat-transfer material being disposed between the module for use in a high-temperature portion and the module for use in a low-temperature portion.

Item 2. A stacked thermoelectric conversion module having a structure wherein a module for use in a high-temperature portion and a module for use in a low-temperature portion are stacked:

the module for use in a high-temperature portion being a thermoelectric conversion module comprising a metal oxide as each thermoelectric conversion material or a thermoelectric conversion module comprising a silicon-based alloy as each thermoelectric conversion material;

the module for use in a low-temperature portion being a thermoelectric conversion module comprising a bismuth-tellurium-based alloy as each thermoelectric conversion material,

the stacked thermoelectric conversion module further comprising a cooling member disposed at a cooling surface side of the module for use in a low-temperature portion; and

a flexible heat-transfer material being disposed between the module for use in a low-temperature portion and the cooling member.

Item 3. The stacked thermoelectric conversion module according to Item 1, wherein a cooling member is disposed at the cooling surface side of the module for use in a low-temperature portion, and a flexible heat-transfer material is disposed between the module for use in a low-temperature portion and the cooling member.

Item 4. The stacked thermoelectric conversion module according to Item 1 or 3, wherein, in addition to the flexible heat-transfer material, a metal plate is disposed between the module for use in a high-temperature portion and the module for use in a low-temperature portion.

Item 5. The stacked thermoelectric conversion module according to any one of claims 1 to 4,

the module for use in a high-temperature portion and the module for use in a low-temperature portion each comprising a plurality of thermoelectric conversion elements in which one end of a p-type thermoelectric conversion material and one end of an n-type thermoelectric conversion material are electrically connected, and

the plurality of thermoelectric conversion elements being connected in series by electrically connecting an unconnected end of a p-type thermoelectric conversion material of one thermoelectric conversion element to an unconnected end of an n-type thermoelectric conversion material of another thermoelectric conversion element,

wherein

(i) the thermoelectric conversion element forming a module for use in a high-temperature portion comprises a p-type thermoelectric conversion material of a complex oxide represented by the formula: CaₐM_{b}Co₄O_{c}, wherein M is one or more elements selected from the group consisting of Na, K, Li, Ti, V, Cr, Mn, Fe, Ni, Cu, Zn, Pb, Sr, Ba, Al, Bi, Y and lanthanide, where 2.2≦a≦3.6; 0≦b≦0.8; 8≦c≦10; and an n-type thermoelectric conversion material of a complex oxide represented by the formula: Ca₁₋ₓM¹ₓMn_{1-y}M²_{y}O_{z}, wherein M¹ is at least one element selected from the group consisting of Ce, Pr, Nd, Sm, Eu, Gd, Yb, Dy, Ho, Er, Tm, Tb, Lu, Sr, Ba, Al, Bi, Y and La; M² is at least one element selected from the group consisting of Ta, Nb, W and Mo; and x, y and z are in the ranges of 0≦x≦0.5, 0≦y≦0.2, 2.7≦z≦3.3; or

the thermoelectric conversion element forming a module for use in a high-temperature portion comprises a p-type thermoelectric conversion material of a silicon-based alloy represented by the formula: Mn₁₋ₓM^{a}ₓSi_{1.6-1.8}, wherein M^{a} is one or more elements selected from the group consisting of Ti, V, Cr, Fe, Ni and Cu; 0≦x≦0.5; and an n-type thermoelectric conversion material of a silicon-based alloy represented by the formula: Mn₃₋ₓM¹ₓSi_{y}Al_{z}M²ₐ, wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1; and

(ii) the thermoelectric conversion element forming a module for use in a low-temperature portion comprises a p-type thermoelectric conversion material of a bismuth-tellurium-based alloy represented by the formula: Bi₂₋ₓSbₓTe₃, wherein 0.5≦x≦1.8; and an n-type thermoelectric conversion material of a bismuth-tellurium-based alloy represented by the formula: Bi₂Te₃₋ₓSeₓ, wherein 0.01≦x≦0.3.

Item 6. The stacked thermoelectric conversion module according to any one of Items 1 to 5, wherein the flexible heat-transfer material is a resin-based paste material or a resin-based sheet material each having a thermal resistivity of approximately 1 mK/W or less.

Item 7. A stacked thermoelectric conversion module according to any one of Items 3 to 6, wherein the metal plate is an aluminum plate.

The stacked thermoelectric conversion module of the present invention comprises two types of thermoelectric conversion modules stacked onto each other. One of the two thermoelectric conversion modules is disposed at a location that is in contact with a high-temperature heat source to collect heat from the heat source (hereunder, this thermoelectric conversion module may be referred to as a “module for use in a high-temperature portion”), and the other thermoelectric conversion module is disposed at a location that is in contact with a low-temperature atmosphere to cool one surface of the thermoelectric conversion material (hereunder, this thermoelectric conversion module may be referred to as a “module for use in a low-temperature portion”). Each component of the stacked thermoelectric conversion module of the present invention is explained in detail below.

### (I) Thermoelectric Conversion Materials for a Module for Use in a High-Temperature Portion

The module for use in a high-temperature portion used in the present invention is a thermoelectric conversion module that comprises a metal oxide as each thermoelectric conversion material, or that comprises a silicon-based alloy as each thermoelectric conversion material. These thermoelectric conversion materials exhibit excellent thermoelectric performance and are highly stable at high temperatures, allowing them to be used stably for a long period of time even when a high-temperature heat source of 400° C. or higher, such as waste heat exhausted from an industrial furnace, waste incinerator, or automobile, is used. Thermoelectric conversion materials of a metal oxide, and thermoelectric conversion materials of a silicon-based alloy are specifically explained below.

### (i) Thermoelectric Conversion Material of a Metal Oxide

The metal oxides used as the thermoelectric conversion material for a module for use in a high-temperature portion are not particularly limited as long as they are capable of exhibiting excellent performance as a p-type thermoelectric conversion material or an n-type thermoelectric conversion material at a target high-temperature region.

In particular, when a complex oxide represented by the formula: CaₐM_{b}Co₄O_{c}, wherein M is one or more elements selected from the group consisting of Na, K, Li, Ti, V, Cr, Mn, Fe, Ni, Cu, Zn, Pb, Sr, Ba, Al, Bi, Y and lanthanide, where 2.2≦a≦3.6; 0≦b≦0.8; and 8≦c≦10, is used as the p-type thermoelectric conversion material; and a complex oxide represented by the formula: Ca₁₋ₓM¹ₓMn_{1-y}M²_{y}O_{z}, wherein M¹ is at least one element selected from the group consisting of Ce, Pr, Nd, Sm, Eu, Gd, Yb, Dy, Ho, Er, Tm, Tb, Lu, Sr, Ba, Al, Bi, Y and La; M² is at least one element selected from the group consisting of Ta, Nb, W and Mo; and x, y and z respectively are in the ranges of 0≦x≦0.5, 0≦y≦0.2, and 2.7≦z≦3.3, is used as the n-type thermoelectric conversion material, a thermoelectric conversion element comprising the above complex oxides in combination is capable of efficiently performing thermoelectric power generation when a high-temperature heat source of about 700 to 900° C. is used. This also allows the use of a high-temperature heat source of about 1100° C.

Among these thermoelectric conversion materials, the complex oxide presented by formula: CaₐM_{b}Co₄O_{c} that is used as a p-type thermoelectric conversion material has the structure wherein a rock salt structure layer and a CoO₂ layer are alternately stacked onto each other. The rock salt structure layer has a compositional formula (Ca,M)₂CoO₃ composed of Ca, M, Co and O. The CoO₂ layer has octahedrons with octahedral coordination of six O to one Co wherein the octahedrons are arranged two-dimensionally so they share each other's sides. The p-type thermoelectric conversion material having such a structure exhibits a high Seebeck coefficient and excellent electrical conductivity.

The complex oxide used as an n-type thermoelectric conversion material and represented by the formula: Ca₁₋ₓM¹ₓMn_{1-y}M²_{y}O_{z}, wherein M¹ is at least one element selected from the group consisting of Ce, Pr, Nd, Sm, Eu, Gd, Yb, Dy, Ho, Er, Tm, Tb, Lu, Sr, Ba, Al, Bi, Y and La; M² is at least one element selected from the group consisting of Ta, Nb, W and Mo; and x, y and z are in the ranges of 0≦x≦0.5, 0≦y≦0.2, and 2.7≦z≦3.3, exhibits excellent n-type thermoelectrical characteristics and is desirably usable as an n-type thermoelectric conversion material with excellent durability. In particular, a sintered body of the complex oxide in which 50% or more crystal particles composing a sintered body have a particle size of 1 μm or less is preferable. Such a sintered body has a negative Seebeck coefficient at a temperature of 100° C. or higher and has electric resistivity of 50 mΩ·cm or less at a temperature of 100° C. or higher. Accordingly, the sintered body exhibits excellent thermoelectric conversion capability as an n-type thermoelectric conversion material and has sufficient fracture strength.

### (ii) Thermoelectric Conversion Material of a Silicon-Based Alloy

Among thermoelectric conversion materials of a silicon-based alloy, it is preferable to use, as a p-type thermoelectric conversion material, a silicon-based alloy represented by the formula: Mn₁₋ₓM^{a}ₓSi_{1.6-1.8}, wherein M^{a} is one or more elements selected from the group consisting of Ti, V, Cr, Fe, Ni and Cu; 0≦x≦0.5; and, as an n-type thermoelectric conversion material, a silicon-based alloy represented by the formula: Mn₃₋ₓM¹ₓSi_{y}Al_{z}M²ₐ, wherein M¹ is at least one element selected from the group consisting of Ti, V, Cr, Fe, Co, Ni, and Cu; and M² is at least one element selected from the group consisting of B, P, Ga, Ge, Sn, and Bi, where 0≦x≦3.0, 3.5≦y≦4.5, 2.5≦z≦3.5, and 0≦a≦1.

A thermoelectric conversion element comprising these silicon-based alloys in combination exhibits a high thermoelectric conversion efficiency, in particular, in the case where the heat source is in the temperature range of about 300 to 600° C.

Among these materials, the alloy used as a p-type thermoelectric conversion material and represented by the formula: Mn₁₋ₓM^{a}ₓSi_{1.6-1.8}, wherein M^{a} is one or more elements selected from the group consisting of Ti, V, Cr, Fe, Ni and Cu; where 0≦x≦0.5, is a known material.

The silicon-based alloy that is used as an n-type thermoelectric conversion material and that is represented by the formula: Mn₃₋ₓM¹ₓSi_{y}Al_{z}M²ₐ, wherein M¹ is at least one element selected from the group consisting of Ti, V, Cr, Fe, Co, Ni, and Cu; and M² is at least one element selected from the group consisting of B, P, Ga, Ge, Sn, and Bi, where 0≦x≦3.0, 3.5≦y≦4.5, 2.5≦z≦3.5, and 0≦a≦1, is a novel metal material as an n-type thermoelectric conversion material. This material has a negative Seebeck coefficient at temperatures in the range of 25 to 700° C.; and has a high negative Seebeck coefficient at the temperature of 600° C. or below, in particular, in the range of about 300 to 500° C. The metal material exhibits a very low electric resistivity of 1 mΩ·cm or less in the temperature range of 25 to 700° C. Accordingly, the metal material exhibits excellent thermoelectric conversion capability as an n-type thermoelectric conversion material in the aforementioned temperature range. Furthermore, the metal material has excellent heat resistance, oxidation resistance, etc. For example, there is almost no deterioration in its thermoelectric conversion performance, even when used for a long period of time in the temperature range of about 25 to 700° C.

There is no particular limitation to the method for producing the alloy described above. In one example, the raw materials are mixed in such a manner that the element ratio thereof becomes the same as that of the target alloy, after which the raw material mixture is melted under a high temperature, and then cooled. Examples of usable raw materials include, in addition to elementary metals, intermetallic compounds and solid solutions comprising a plurality of constituent elements, and composites thereof (such as alloys). There is no particular limitation to the method for melting the raw materials; for example, the raw materials may be heated to a temperature exceeding the melting point of the raw material phase or product phase by arc melting method or other methods. In order to prevent the oxidation of the raw materials, the melting is preferably performed under a non-oxidizing atmosphere, for example, under an inert gas atmosphere, such as a helium or argon atmosphere; or under a reduced-pressure atmosphere. By cooling the melt of the metals that is obtained by the above method, an alloy represented by the compositional formula above can be formed. Furthermore, by conducting a heat treatment on the resulting alloy, if necessary, a more homogeneous alloy can be obtained, thereby enhancing its capability as a thermoelectric conversion material. In this case, the conditions for the heat treatment are not particularly limited. Although it depends on the types, amounts, etc., of the metallic elements contained, the heat treatment is preferably conducted at a temperature in the range of about 1450 to 1900° C. In order to prevent the oxidation of the metal material, the heat treatment is preferably conducted under a non-oxidizing atmosphere, such as when melting is performed.

### (II) Thermoelectric Conversion Materials for a Module for Use in a Low-Temperature Portion

In a thermoelectric conversion module that is in contact with a low-temperature atmosphere, a bismuth-tellurium-based alloy is used as each thermoelectric conversion material. More specifically, a bismuth-tellurium-based alloy represented by the formula: Bi₂₋ₓSbₓTe₃, wherein 0.5≦x≦1.8, is used as a p-type thermoelectric conversion material and a bismuth-tellurium-based alloy represented by the formula: Bi₂Te₃₋ₓSeₓ, wherein 0.01≦x≦0.3, is used as an n-type thermoelectric conversion material. A thermoelectric conversion element comprising these bismuth-tellurium-based alloys as its thermoelectric conversion materials can be heated up to about 200° C. in a high-temperature portion and exhibits excellent thermoelectric performance when the low-temperature portion is at a temperature of about 20 to 100° C.

### (III) Structures of Thermoelectric Conversion Modules

The structures of the module for use in a high-temperature portion and the module for use in a low-temperature portion constituting the stacked thermoelectric conversion module of the present invention are not particularly limited. One example of the structure of each module is that one end of a p-type thermoelectric conversion material is electrically connected to one end of an n-type thermoelectric conversion material to form a thermoelectric conversion element, and a plurality of such thermoelectric conversion elements are connected by electrically connecting an unconnected end of a p-type thermoelectric conversion material of one thermoelectric conversion element to an unconnected end of an n-type thermoelectric conversion material of another thermoelectric conversion element. This results in a module having a structure wherein a plurality of thermoelectric conversion elements are electrically connected in series. The thermoelectric conversion module is explained in detail below.

### (i) Thermoelectric Conversion Element

Each thermoelectric conversion element constituting the thermoelectric conversion module has a structure wherein one end of a p-type thermoelectric conversion material is electrically connected to one end of an n-type thermoelectric conversion material.

The shapes, sizes, and the like of the p-type thermoelectric conversion material and the n-type thermoelectric conversion material are not particularly limited and are suitably selected to exert the necessary thermoelectric conversion performance, depending on power generation ability, size, shape and the like of the target thermoelectric power generation module.

There is no limitation to the method for electrically connecting one end of a p-type thermoelectric conversion material to one end of an n-type thermoelectric conversion material. Preferable is the method which allows excellent thermoelectromotive force to be obtained and low electric resistance to be achieved when connected. Specific examples of the methods include bonding one end of a p-type thermoelectric conversion material and one end of an n-type thermoelectric conversion material to a conductive material (electrode) using a binder; bonding by pressing or sintering one end of a p-type thermoelectric conversion material to one end of an n-type thermoelectric conversion material directly or via a conductive material; and bringing a p-type thermoelectric conversion material into electrical contact with an n-type thermoelectric conversion material using a conductive material. FIG. 1 is a schematic diagram illustrating an example of a thermoelectric conversion element obtained by bonding one end of a p-type thermoelectric conversion material and one end of an n-type thermoelectric conversion material to a conductive material (electrode).

### (ii) Thermoelectric Conversion Module

Each of the modules for use in a high-temperature portion and for use in a low-temperature portion used in the stacked thermoelectric conversion module of the present invention uses a plurality of the above-described thermoelectric conversion elements. In each module, a plurality of thermoelectric conversion elements are connected in series by electrically connecting an unconnected end of a p-type thermoelectric conversion material of one thermoelectric conversion element to an unconnected end of an n-type thermoelectric conversion material of another thermoelectric conversion element.

A generally employed method is such that unconnected ends of thermoelectric conversion elements are bonded to an insulating substrate using a binder so that one end of a p-type thermoelectric conversion material of one thermoelectric conversion element is electrically connected to one end of an n-type thermoelectric conversion material of another thermoelectric conversion element on the substrate.

The shape of the module is not particularly limited. In order to form a stacked module, each module constituting the stacked module preferably has a plate-like shape as a whole. Furthermore, in order to perform efficient power generation, the substrate surface where the thermoelectric conversion materials are bonded is preferably large in area. For ease of production, a square or a rectangular planar shape is desirable.

Concentrically stacked cylindrical modules can be cooled in an efficient manner by flowing a heat transfer medium, such as cooling water, inside the modules.

The size of each module is not particularly limited. Considering deformation and breakage due to thermal stress and the like, the length of the module in the lengthwise and crosswise directions is preferably 100 mm or less, and more preferably 65 mm or less. The size of each module can be suitably selected depending on the temperature conditions and the like of the heat source and cooling member so as to optimize the electric power generating performance. The thickness of each module is also not particularly limited and may be suitably selected depending on the temperature of the heat source on the high-temperature side. When the temperature of the heat source is up to about 1100° C., the thickness is generally 3 to 20 mm.

FIG. 2 is a schematic diagram illustrating the structure of a thermoelectric conversion module having a plurality of thermoelectric conversion elements bonded to a substrate using a binder.

The thermoelectric power generation module shown in FIG. 2 comprises the element shown in FIG. 1 as each thermoelectric conversion element, wherein each element is disposed in such a manner that the unconnected ends of the p-type thermoelectric conversion material and the n-type thermoelectric conversion material are in contact with the substrate, and the thermoelectric conversion element is bonded on the substrate using a binder so that the p-type thermoelectric conversion material and the n-type thermoelectric conversion material are connected in series.

The substrate is used mainly for improving thermal uniformity and mechanical strength and for maintaining electrical insulation and the like. The material for the substrate is not particularly limited. Preferably used materials are those that do not melt or break at the temperature of a high temperature heat source, that are chemically stable, that are insulating materials which do not react with a thermoelectric conversion material, binder or the like, and that have high thermal conductivity. By using a substrate having high thermal conductivity, the temperature of the high-temperature portion of the element can be brought near to the temperature of the high heat source, thus making it possible to increase the generated voltage. Because an oxide is used as the thermoelectric conversion material in the present invention, considering the coefficient of thermal expansion, etc., an oxide ceramic, such as alumina, is preferably used as the material for the substrate.

In bonding each thermoelectric conversion element to the substrate, use of a binder that is capable of connecting the element with low resistance is preferable. For example, a paste comprising a noble metal such as silver, gold and platinum; solder; platinum wire; or the like is preferably used.

The number of thermoelectric conversion elements used in a single module is not limited and can be suitably selected depending on the necessary electric power.

In each thermoelectric conversion element bonded to the substrate, the surface opposite to that bonded to the substrate may be such that the connecting portion (electrode) between the p-type thermoelectric conversion material and the n-type thermoelectric conversion material is exposed or an insulating substrate is disposed on the connecting portion between the p-type thermoelectric conversion material and the n-type thermoelectric conversion material. Providing an insulating substrate can maintain the strength of each module, and improve the thermal contact when contacted with another module or component. In order to decrease the thermal resistance, the substrate is preferably as thin as possible within the range that can achieve the objects mentioned above.

(iii) Stacked Thermoelectric Conversion Module

The stacked thermoelectric conversion module of the present invention has a structure wherein the module for use in a high-temperature portion and the module for use in a low-temperature portion are stacked, and a flexible heat-transfer material is disposed between the module for use in a high-temperature portion and the module for use in a low-temperature portion.

When the substrate surface of the module for use in a high-temperature portion is placed on the substrate surface of the module for use in a low-temperature portion, a flexible heat-transfer material may be disposed between the substrates. When at least one of the modules for use in a high-temperature portion and for use in a low-temperature portion has a surface that is not provided with a substrate, the modules may be stacked in such a manner that the surface where the connecting portion (electrode) between the p-type thermoelectric conversion material and the n-type thermoelectric conversion material is exposed, i.e., the surface that is not provided with a substrate, is in contact with the other module. In this case, a flexible heat-transfer material may be disposed in the area in which the modules are in contact with each other. This also ensures electrical insulation between the modules.

As the flexible heat-transfer material, a material that has the flexibility to fill the gap formed between the module for use in a high-temperature portion and the module for use in a low-temperature portion, and that has a lower thermal resistivity than that of air can be used. By disposing such a heat-transfer material between the module for use in a high-temperature portion and the module for use in a low-temperature portion, the gap formed between the module for use in a high-temperature portion and the module for use in a low-temperature portion can be filled, and the heat transfer performance from the module for use in a high-temperature portion to the module for use in a low-temperature portion can be improved, enhancing the thermoelectric conversion efficiency. Furthermore, this makes it possible to follow up the thermal deformation produced during thermoelectric power generation and to prevent breakage of the module due to thermal deformation.

The flexible heat-transfer material may be a material in the form of a paste, a sheet or the like. Specifically, a material having the flexibility to fill the gap formed between the module for use in a high-temperature portion and the module for use in a low-temperature portion may be used. In terms of the heat transfer performance, the material is required to have a thermal resistivity lower than 40 mK (meter kelvin)/W, which is the thermal resistivity of air. In particular, in order to effectively perform thermoelectric power generation, the thermal resistivity is preferably about 1 mK/W or lower, which is assumed to be the total thermal resistivity of the two types of modules, and more preferably about 0.6 mK/W or lower.

As such flexible heat-transfer materials, resin-based paste materials and resin-based sheet materials may be used. Paste materials are particularly preferable when the connecting area between the module for use in a high-temperature portion and the module for use in a low-temperature portion has holes and/or deformation, since such materials can fill small holes, etc., and improve the heat transfer performance when applied to the surface of a module or the surface of a cooling member. Sheet-shaped heat-transfer materials are desirably used in modules that easily deform during use, since they can easily follow up the thermal deformation, fill the gap formed during power generation, and prevent breakage due to deformation.

Among such flexible heat-transfer materials, examples of paste heat-transfer materials include the materials that comprise, as base components, silicone oil, fluororesin, epoxy resin and like liquid resin components that have sufficient heat tolerance property at temperatures of the portion to which the heat-transfer material is disposed, and further comprise, as a filler, an inorganic powder of alumina, silicon, silicon carbide, silicon oxide, or silicon nitride to improve the thermal conductivity, in consideration of the specific conditions when the stacked thermoelectric conversion module is actually used. The amount of filler added to the paste heat-transfer material is not particularly limited. In order to achieve sufficient heat transfer performance, for example, the amount of filler is desirably selected to be such an amount that a coating film formed of the paste heat-transfer material has a thermal resistivity of about 1 mK/W or less. It is important that the paste heat-transfer material have adequate hardness and flexibility so that it can fill the small holes and unevenness in the connecting area between the module for use in a high-temperature portion and the module for use in a low-temperature portion. The paste heat-transfer material preferably has a consistency number of about No. 0 to No. 4 measured based on the grease-composition consistency measuring method defined in JIS K 2220, more preferably No. 0 to No. 2, and still more preferably No. 1. Note that, consistency number of No. 1 corresponds to a consistency in the range of 310 to 340. Specific examples of such paste heat-transfer materials include a commercially available silicone paste (tradename: SH 340 COMPOUND; manufactured by Dow Corning Toray Co., Ltd.), which comprises silicone oil and a filler such as alumina mixed therein.

Also, in terms of sheet-shaped resin-based heat-transfer materials, usable examples are the sheet-shaped heat-transfer materials that comprise, as a binder component, resins such as silicone resin, fluororesin and epoxy resin that have sufficient heat tolerance property at a temperature of the portion to which the heat-transfer material is disposed, and further comprise, as a filler, an inorganic powder of alumina, silicon, silicon carbide, silicon oxide, or silicon nitride that have thermal conductivity, in consideration of the specific conditions when the stacked thermoelectric conversion module is used. Also in this case, in order to achieve sufficient heat transfer performance, the amount of the added inorganic powder is, as in the case where a paste material is used as described above, for example, preferably selected in such a manner that the thermal resistivity becomes about 1 mK/W or lower. The sheet-shaped material is required to have not only sufficient softness but also adequate elasticity in order to fill the gap of the connecting area between the module for use in a high-temperature portion and the module for use in a low-temperature portion and to follow up various kinds of deformation such as thermal deformation of the stacked thermoelectric conversion module. The material desirably has a penetration (JIS K2207), which indicates softness, of about 30 to 100, and more preferably about 40 to 90. The compression permanent strain (measured based on JIS K 6249), which indicates elasticity, is preferably about 30 to 80%, and more preferably about 45 to 70%. Examples of such sheet-shaped materials include a commercially available sheet material (such as tradename λ GEL COH4000, manufactured by Taika Corporation), which comprises silicone as a main component and a thermally conductive filler as an additive.

The thickness of the layer formed of a flexible heat-transfer material is not particularly limited as long as it is sufficient to fill the gap formed between the modules. The thickness may be generally about 0.5 to 2 mm.

In the present invention, when the surfaces of the two types of modules, which are in contact with each other, have different sizes, some elements in the larger module are in a condition that they are exposed to the atmosphere. This causes an uneven temperature in the same module, lowering the power generating efficiency. In order to solve this problem, it is preferable that a metal plate, such as an aluminum plate, that can cover the entire surface of the module be inserted between the modules together with a heat-transfer material. This eliminates unevenness in the temperature and improves the power generating efficiency.

The portion to which the metal plate is disposed is not particularly limited as long as it is located between the module for use in a high-temperature portion and the module for use in a low-temperature portion, and may be freely selected from portions, such as a portion that comes in contact with the module for use in a high-temperature portion, a portion that comes in contact with the module for use in a low-temperature portion, or the like. Alternatively, a structure may be employed where a metal plate is located between the modules in such a manner that the metal plate is inserted between the flexible heat-transfer materials so that the gap formed between the metal plate and each module can be filled. FIG. 3 is a schematic diagram illustrating the structure of the stacked thermoelectric conversion module of the present invention. In FIG. 3, (a) shows a module in which a flexible heat-transfer material is disposed between the module for use in a high-temperature portion and the module for use in a low-temperature portion, (b) and (c) show modules in which a flexible heat-transfer material and a metal plate are disposed between the module for use in a high-temperature portion and the module for use in a low-temperature portion, and (d) shows a module in which a laminate of a flexible heat-transfer material, a metal plate and a flexible heat-transfer material is disposed between the module for use in a high-temperature portion and the module for use in a low-temperature portion.

When the thickness of the metal plate (aluminum plate) is unduly thin, warping occurs, but when the thickness thereof is unduly thick, the heat transfer coefficient lowers. The most preferable thickness is usually about 0.5 to 2 mm, although it depends on the structure of the stacked body.

### (iv) Heat-Collecting Member and Cooling Member

The stacked thermoelectric conversion module of the present invention having the above-described structure may further comprise, if necessary, a heat-collecting member on the surface of the module for use in a high-temperature portion, which comes in contact with the heat source. This makes it possible to effectively collect heat from the heat source. The structure of a heat-collecting member is not particularly limited and, for example, when the heat source is a gas, in order to widen the heat transfer area, a fin-type heat-collecting member may be provided. The materials for the heat-collecting member may be suitably selected depending on the temperature, environment, or the like during power generation, among which those having a high thermal conductivity are preferable. For example, if the temperature of the heat source is about 600° C. or lower, aluminum is preferable since it is inexpensive and light in weight. If the temperature of the heat source exceeds 600° C., iron or the like may be used from the viewpoint of melting point, cost, or the like.

Furthermore, in the stacked thermoelectric conversion module of the present invention, a cooling member can be disposed on the cooling surface of the module for use in a low-temperature portion, if necessary. The shape of the cooling member is also not particularly limited and may be suitably selected depending on the types of the heat transfer media as long as it can cool the module efficiently. For example, if the heat transfer media is in a gas form, providing a fin-type cooling member can allow efficient cooling to be performed. FIG. 4 is a schematic diagram illustrating the structure of the stacked thermoelectric conversion module shown in FIG. 3 (a), wherein a heat-collecting member is disposed on the heating surface of the module for use in a high-temperature portion, which comes in contact with heat source, and a cooling member is disposed on the cooling surface of the module for use in a low-temperature portion.

When a cooling member is disposed on the cooling surface of the module for use in a low-temperature portion, the gap formed between the module for use in a low-temperature portion and the cooling member can be filled by disposing a flexible heat-transfer material between the module for use in a low-temperature portion and the cooling member, so that the heat transfer performance from the module for use in a low-temperature portion to the cooling member can be improved and the thermoelectric conversion efficiency can be increased accordingly. Furthermore, this arrangement allows the module to follow up the thermal deformation generated during thermoelectric power generation and prevents breakage of the module due to thermal deformation.

Here, usable examples of the flexible heat-transfer material are the same as those for the flexible heat transfer material disposed between the substrate surface of the module for use in a high-temperature portion and the module for use in a low-temperature portion.

### Advantageous Effects of Invention

The stacked thermoelectric conversion module of the present invention has a structure wherein a module for use in a high-temperature portion and a module for use in a low-temperature portion are stacked onto each other. The module for use in a high-temperature portion uses a metal oxide or a silicon-based alloy as each thermoelectric conversion material that exhibits excellent thermoelectric conversion efficiency in high-temperature regions. The module for use in a low-temperature portion uses a bismuth-tellurium-based alloy as each thermoelectric conversion material that exhibits high thermoelectric conversion efficiency in the range of room temperature to about 200° C. The stacked thermoelectric conversion module achieves power generation in an efficient manner using waste heat in a wide temperature range of about 300 to 1100° C.

By disposing a flexible heat-transfer material at the connecting area between the module for use in a high-temperature portion and the module for use in a low-temperature portion or at the connecting area between the module for use in a low-temperature portion and the cooling member, the stacked thermoelectric conversion module of the present invention exhibits improved heat transfer performance and has a high thermoelectric conversion efficiency and further breakage of the module due to thermal deformation can also be prevented.

Therefore, the stacked thermoelectric conversion module of the present invention can achieve thermoelectric power generation using, as a heat source, waste heat in a wide ranging temperature region in an efficient and safe manner for a long period of time.

### BRIEF DESCRIPTION OF DRAWINGS

FIG. 1 is a schematic diagram illustrating one example of a thermoelectric conversion element.

FIG. 2 is a schematic diagram illustrating one example of thermoelectric conversion modules used for a module for use in a high-temperature portion and a module for use in a low-temperature portion.

FIG. 3 schematically illustrates the structures of the stacked thermoelectric conversion modules of the present invention.

FIG. 4 is a schematic diagram illustrating the structure of a stacked thermoelectric conversion module provided with a heat-collecting member and a cooling member.

FIG. 5 is a schematic diagram illustrating the structure of the module for use in a high-temperature portion used in Examples 1 to 4 and Comparative Example 1.

FIG. 6 is a schematic diagram illustrating the structure of the module for use in a low-temperature portion used in Examples 1 to 4 and Comparative Example 1.

FIG. 7 schematically illustrates the structures of the stacked thermoelectric conversion modules used in Examples 1 to 4 and Comparative Example 1.

FIG. 8 is a schematic diagram illustrating the structure of the module for use in a high-temperature portion used in Examples 9 to 11 and Comparative Example 3.

FIG. 9 schematically illustrates the structures of the stacked thermoelectric conversion modules used in Examples 1 to 4 and Comparative Example 1.

FIG. 10 is a graph showing the temperature dependency of the Seebeck coefficients of the sintered bodies of a metal material obtained in Reference Examples 1 to 3 measured in the air at 25 to 700° C.

FIG. 11 is a graph showing the temperature dependency of the electric resistivity of the sintered bodies of a metal material obtained in Reference Examples 1 to 3 measured in the air at 25 to 700° C.

FIG. 12 is a graph showing the temperature dependency of the thermal conductivity of the sintered body of a metal material obtained in Reference Example 1 measured in the air at 25 to 700° C.

FIG. 13 is a graph showing the temperature dependency of the dimensionless figure of merit (ZT) of the sintered body of a metal material obtained in Reference Example 1 measured in the air at 25 to 700° C.

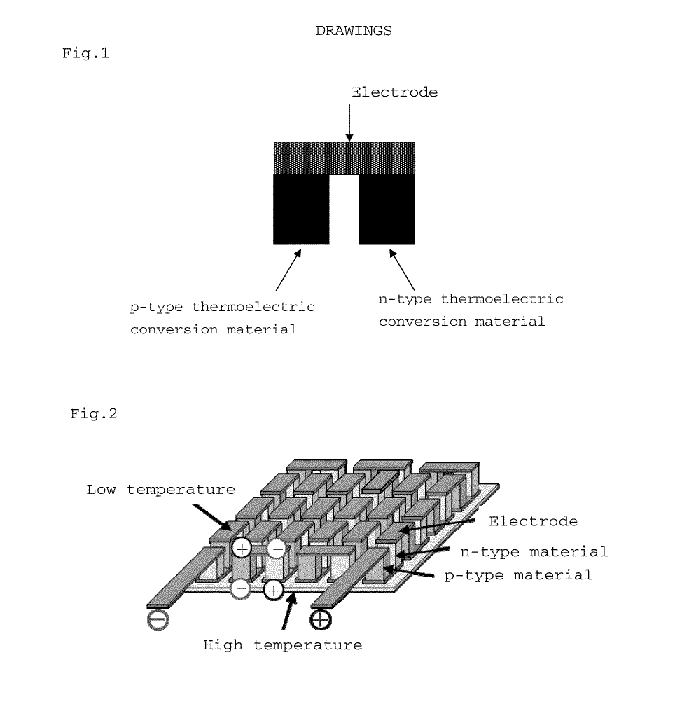

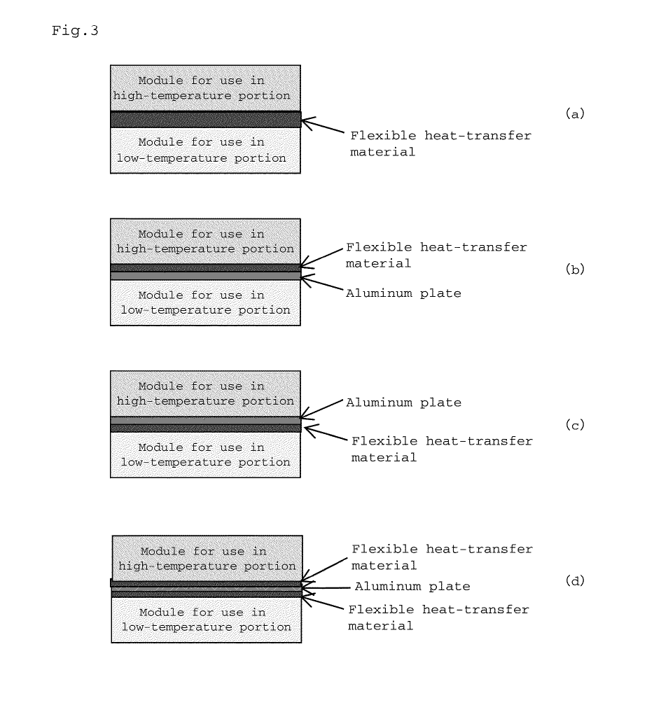

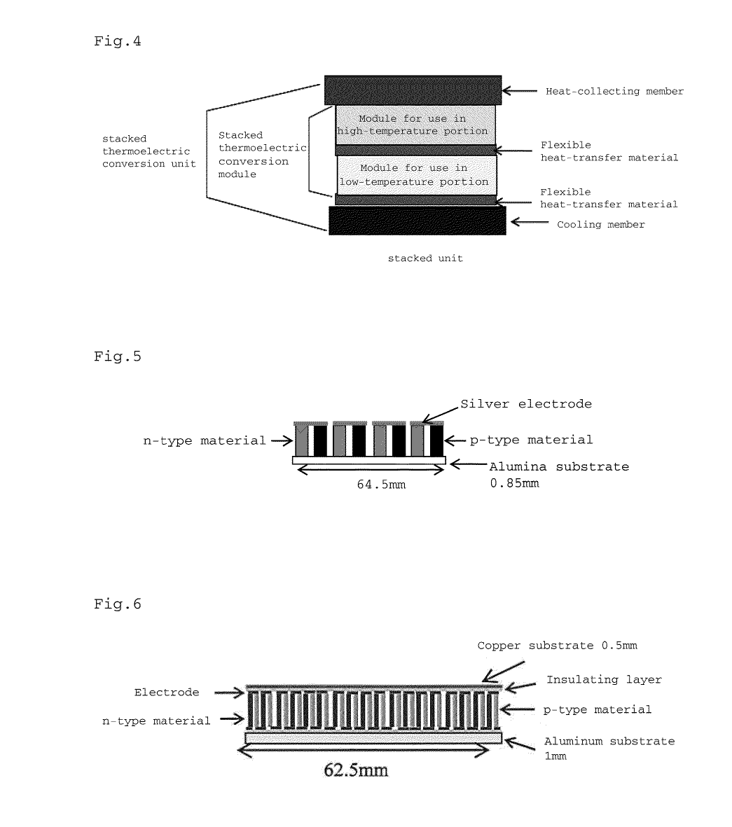

### DESCRIPTION OF EMBODIMENTS

The present invention is explained in detail with reference to the Examples.

### Example 1

### (1) Production of a Module for Use in a High-Temperature Portion

A p-type thermoelectric conversion material composed of a Ca_{2.7}Bi_{0.3}Co₄O₉ sintered body having a rectangular column shape with a cross section of 7.0 mm×3.5 mm and a height of 7 mm, and an n-type thermoelectric conversion material composed of a CaMn_{0.98}Mo_{0.02}O₃ sintered body having a rectangular column shape with a cross section of 7.0 mm×3.5 mm and a height of 7 mm were connected to a silver plate (electrode) having a size of 7.1 mm×7.1 mm and a thickness of 0.1 mm, thereby producing a thermoelectric conversion element comprising a pair of a p-type thermoelectric conversion material and an n-type thermoelectric conversion material.

Using an alumina plate having a size of 64.5 mm×64.5 mm and a thickness of 0.85 mm as a substrate, the above-described thermoelectric conversion elements were bonded to the substrate in such a manner that an unconnected end of the p-type thermoelectric conversion material of the thermoelectric conversion element was connected to an unconnected end of the n-type thermoelectric conversion material of another thermoelectric element, thereby producing a thermoelectric power generation module in which 64 pairs of thermoelectric conversion elements were connected in series. Silver paste was used as a binder. The thus-obtained module was used as a module for use in a high-temperature portion. FIG. 5 shows a schematic diagram of the module for use in a high-temperature portion obtained by this process.

### (2) Production of a Module for Use in a Low-Temperature Portion

A p-type thermoelectric conversion material composed of a bismuth-tellurium alloy represented by Bi_{0.5}Sb_{1.5}Te₃ having a cylindrical shape with a cross sectional diameter of 1.8 mm and a length of 1.6 mm, and an n-type thermoelectric conversion material composed of a bismuth-tellurium alloy represented by Bi₂Te_{2.85}Se_{0.15} having a cylindrical shape with a cross sectional diameter of 1.8 mm and a length of 1.6 mm were soldered to a copper plate having a size of 62 mm×62 mm and a thickness of 0.2 mm, thereby producing a thermoelectric conversion element comprising a pair of a p-type thermoelectric conversion material and an n-type thermoelectric conversion material.

Using an aluminum plate having a size of 62 mm×62 mm and a thickness of 1 mm, on which an insulating coating was formed, as a substrate, the above-described thermoelectric conversion elements were bonded to the substrate in such a manner that an unconnected end of the p-type thermoelectric conversion material of the thermoelectric conversion element was connected to an unconnected end of the n-type thermoelectric conversion material of another thermoelectric conversion element, thereby producing a thermoelectric power generation module in which 311 pairs of thermoelectric conversion elements were connected in series. Silver paste was used as a binder. A copper substrate having an insulating coating thereon and having a size of 62 mm×62 mm and a thickness of 0.5 mm was provided on the surface of the electrode at which a p-type thermoelectric conversion material and an n-type thermoelectric conversion material are connected. The thus-obtained module was used as a module for use in a low-temperature portion. FIG. 6 shows a schematic diagram of the module for use in a low-temperature portion obtained by this process.

### (3) Production of a Stacked Thermoelectric Conversion Module

The silver electrode surface of the module for use in a high-temperature portion was placed on the aluminum substrate surface of the module for use in a low-temperature portion via a thermal conductive sheet (tradename: λ GEL COH4000, penetration: 40 to 90, compression permanent strain: 49 to 69%, thermal resistivity: 0.15 mK/W) (manufactured by Taika Corporation) (size: 64.5 mm×64.5 mm, thickness: 2 mm), which comprises silicone as a main component and a thermally conductive filler as an additive. A stacked thermoelectric conversion module was thus produced.

### (4) Thermoelectric Power Generation Test

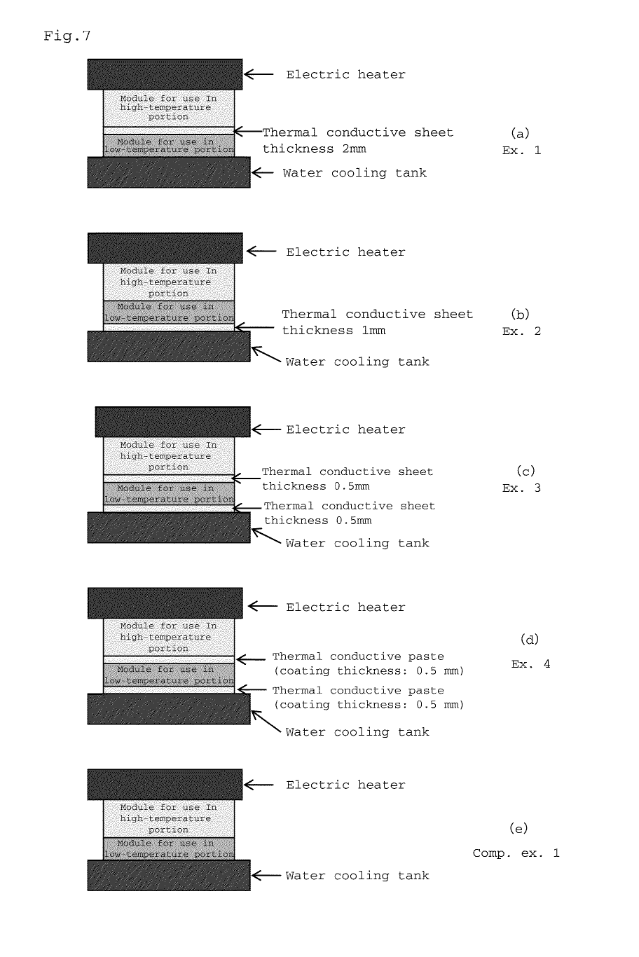

The alumina substrate surface of the module for use in a high-temperature portion of the stacked thermoelectric conversion module produced by the process described above was heated with an electric heater to 500° C. At the same time, an aluminum cooling plate of an aluminum water cooling tank was contacted with the copper substrate surface of the module for use in a low-temperature portion while flowing 20° C. water into the water cooling tank to cool the copper substrate surface, so that thermoelectric power generation was performed. FIG. 7 (a) schematically shows the structure of the stacked thermoelectric conversion module used in this test.

The module for use in a high-temperature portion and the module for use in a low-temperature portion of the stacked thermoelectric conversion module were connected in series. The thermoelectric power generated by the above method was measured while varying the external resistance using an electronic load device. Table 1 shows the maximum output values in each example.

### Example 2

A stacked thermoelectric conversion module was produced using the module for use in a high-temperature portion and the module for use in a low-temperature portion each obtained in Example 1, wherein the module for use in a high-temperature portion was directly placed on the module for use in a low-temperature portion without having a thermal conductive sheet therebetween. An aluminum cooling plate of an aluminum water cooling tank was contacted with the copper substrate surface of the module for use in a low-temperature portion in this stacked module via a 1 mm-thick thermal conductive sheet (tradename: λ GEL COH4000) (manufactured by Taika Corporation), which comprises silicone as a main component and a thermally conductive filler as an additive. The alumina substrate surface of the module for use in a high-temperature portion of the stacked thermoelectric conversion module was heated with an electric heater to 800° C., and the copper substrate surface of the module for use in a low-temperature portion was cooled by flowing 20° C. water into the water cooling tank, so that thermoelectric power generation was performed. FIG. 7(b) schematically shows the structure of the stacked thermoelectric conversion module thus obtained. Table 1 shows the maximum output values measured in the same manner as in Example 1.

### Example 3

A stacked thermoelectric conversion module was produced using the module for use in a high-temperature portion and the module for use in a low-temperature portion each obtained in Example 1, wherein the silver electrode surface of the module for use in a high-temperature portion was placed on the aluminum substrate surface of the module for use in a low-temperature portion via a thermal conductive sheet (tradename: λ GEL COH4000) (manufactured by Taika Corporation) (size: 64.5 mm×64.5 mm, thickness: 0.5 mm), which comprises silicone as a main component and a thermally conductive filler as an additive, and an aluminum cooling plate of an aluminum water cooling tank was contacted with the copper substrate surface of the module for use in a low-temperature portion via the same thermal conductive sheet. FIG. 7(c) shows the schematic structure thereof.

The alumina substrate surface of the module for use in a high-temperature portion of the stacked thermoelectric conversion module was heated with an electric heater to 800° C., and the copper substrate surface of the module for use in a low-temperature portion was cooled by flowing 20° C. water into the water cooling tank, so that thermoelectric power generation was performed. Table 1 shows the maximum output values measured in the same manner as in Example 1.

### Example 4

Using the module for use in a high-temperature portion and the module for use in a low-temperature portion each obtained in Example 1, a stacked thermoelectric conversion module was produced in the following manner. That is, a commercially available silicone paste (tradename: SH 340 COMPOUND; manufactured by Dow Corning Toray Co., Ltd.; a consistency of 328-346 (consistency No. 1); a thermal resistivity of approximately 1 mK/W), which comprises silicone oil and alumina mixed therein, was applied to the aluminum substrate surface of the module for use in a low-temperature portion to form a 0.5 mm-thick coating, and the silver electrode surface of the module for use in a high-temperature portion was placed on the coated surface of the module for use in a low-temperature portion. The same paste as used above was applied to the copper substrate surface of the module for use in a low-temperature portion to form a 0.5 mm-thick coating. The coated surface was contacted with an aluminum cooling plate of an aluminum water cooling tank. FIG. 7(d) shows the schematic structure thereof.

The alumina substrate surface of the module for use in a high-temperature portion of the stacked thermoelectric conversion module was heated with an electric heater to 800° C., and the copper substrate surface of the module for use in a low-temperature portion was cooled by flowing 20° C. water into the water cooling tank, so that thermoelectric power generation was performed. Table 1 shows the maximum output values measured in the same manner as in Example 1.

### Comparative Example 1

A stacked thermoelectric conversion module was produced in the same manner as in Example 1 using the module for use in a high-temperature portion and the module for use in a low-temperature portion each obtained in Example 1, except that the modules were directly contacted without disposing a heat-transfer material therebetween. FIG. 7(e) shows the schematic structure thereof.

Using this stacked thermoelectric conversion module, thermoelectric power generation was performed in the same manner as in Example 1. Table 1 shows the maximum output values measured in the same manner as in Example 1.

TABLE 1

| | Heat-transfer | Heat-transfer material | |
|---|---|---|---|
| | material | between module and | |
| | between modules | cooling member | |
| | Thickness (mm) | Thickness (mm) | Output (W) |
| Comparative | None | None | 7.6 |
| Example 1 | | | |
| Example 1 | Thermal | None | 10.8 |
| | conductive | | |
| | sheet | | |
| | 2 mm | | |
| Example 2 | None | Thermal conductive sheet | 11.0 |
| | | 1 mm | |
| Example 3 | Thermal | Thermal conductive sheet | 11.3 |
| | conductive | 0.5 mm | |
| | sheet | | |
| | 0.5 mm | | |
| Example 4 | Thermal | Thermal conductive paste | 11.2 |
| | conductive | 0.5 mm (coating | |
| | paste | thickness) | |
| | 0.5 mm (coating | | |
| | thickness) | | |

### Example 5

A module for use in a high-temperature portion was produced in the same manner as in the production of a module for use in a high-temperature portion in Example 1 except that a p-type thermoelectric conversion material composed of a silicon-based alloy represented by the formula: MnSi_{1.7} having a rectangular column shape with a cross section of 7.0 mm×3.5 mm and a height of 10 mm, and an n-type thermoelectric conversion material composed of a silicon-based alloy represented by the formula: Mn₃Si₄Al₃ having a rectangular column shape with a cross section of 7.0 mm×3.5 mm and a height of 10 mm were used.

Using the module obtained above as the module for use in a high-temperature portion and the same module as that obtained in Example 1 as the module for use in a low-temperature portion, a stacked thermoelectric conversion module was produced in the same manner as in Example 1, wherein a thermal conductive sheet is disposed between the module for use in a high-temperature portion and the module for use in a low-temperature portion.

The alumina substrate surface of the module for use in a high-temperature portion of the stacked thermoelectric conversion module produced in the above process was heated with an electric heater to 600° C. An aluminum cooling plate of an aluminum water cooling tank was contacted with the copper substrate surface of the module for use in a low-temperature portion, and the copper substrate surface of the module for use in a low-temperature portion was cooled by flowing 20° C. water into the water cooling tank, so that thermoelectric power generation was performed.

The module for use in a high-temperature portion and the module for use in a low-temperature portion were connected in series. The thermoelectric power generated in the above method was measured while varying the external resistance using an electronic load device. Table 2 shows the maximum output values in each example.

### Example 6

A stacked thermoelectric conversion module was produced using the same module for use in a high-temperature portion and the same module for use in a low-temperature portion as those used in Example 5, wherein the silver electrode surface of the module for use in a high-temperature portion was directly placed on the aluminum substrate surface of the module for use in a low-temperature portion without having a thermal conductive sheet therebetween. In such a module, an aluminum cooling plate of an aluminum water cooling tank was contacted with the copper substrate surface of the module for use in a low-temperature portion via a 1-mm-thick thermal conductive sheet (tradename: λ GEL COH4000) (manufactured by Taika Corporation), which comprises silicone as a main component and a thermally conductive filler as an additive. The alumina substrate surface of the module for use in a high-temperature portion of the stacked thermoelectric conversion module was heated with an electric heater to 600° C., and the copper substrate surface of the module for use in a low-temperature portion was cooled by flowing 20° C. water into the water cooling tank, so that thermoelectric power generation was performed. Table 2 shows the maximum output values measured in the same manner as in Example 5.

### Example 7

A stacked thermoelectric conversion module was produced using the same module for use in a high-temperature portion and the same module for use in a low-temperature portion as those used in Example 5, wherein the silver electrode surface of the module for use in a high-temperature portion was placed on the aluminum substrate surface of the module for use in a low-temperature portion via a thermal conductive sheet (tradename: λ GEL COH4000) (manufactured by Taika Corporation) (size: 64.5 mm×64.5 mm, thickness: 0.5 mm), which comprises silicone as a main component and a thermally conductive filler as an additive, and an aluminum cooling plate of an aluminum water cooling tank was contacted with the copper substrate surface of the module for use in a low-temperature portion via the same thermal conductive sheet.

The alumina substrate surface of the module for use in a high-temperature portion of the stacked thermoelectric conversion module was heated with an electric heater to 600° C., and the copper substrate surface of the module for use in a low-temperature portion was cooled by flowing 20° C. water into the water cooling tank, so that thermoelectric power generation was performed. Table 2 shows the maximum output values measured in the same manner as in Example 5.

### Example 8

A stacked thermoelectric conversion module was produced using the same module for use in a high-temperature portion and the same module for use in a low-temperature portion as those used in Example 5 in the following manner. That is, a commercially available silicone paste (tradename: SH 340 COMPOUND; manufactured by Dow Corning Toray Co., Ltd.), which comprises silicone oil and alumina mixed therein, was applied to the aluminum substrate surface of the module for use in a low-temperature portion to form a 0.5 mm-thick coating, and the silver electrode surface of the module for use in a high-temperature portion was placed on the coated surface of the module for use in a low-temperature portion. Further, the same paste as that used above was applied to the copper substrate surface of the module for use in a low-temperature portion to form a 0.5 mm-thick coating. The coated surface was contacted with an aluminum cooling plate of an aluminum water cooling tank.

The alumina substrate surface of the module for use in a high-temperature portion of the stacked thermoelectric conversion module was heated with an electric heater to 600° C., and the copper substrate surface of the module for use in a low-temperature portion was cooled by flowing 20° C. water into the water cooling tank, so that thermoelectric power generation was performed. Table 2 shows the maximum output values measured in the same manner as in Example 5.

### Comparative Example 2

A stacked thermoelectric conversion module was produced in the same manner as in Example 5 using the same module for use in a high-temperature portion and the same module for use in a low-temperature portion as those used in Example 5, except that the modules were directly contacted without disposing a heat-transfer material therebetween.

Using this stacked thermoelectric conversion module, thermoelectric power generation was performed in the same manner as in Example 5. Table 2 shows the maximum output values measured in the same manner as in Example 5.

TABLE 2

| | Heat-transfer | Heat-transfer material | |
|---|---|---|---|
| | material | between module and | |
| | between modules | cooling member | |
| | Thickness (mm) | Thickness (mm) | Output (W) |
| Comparative | None | None | 10.5 |
| Example 2 | | | |
| Example 5 | Thermal | None | 13.8 |
| | conductive | | |
| | sheet | | |
| | 2 mm | | |
| Example 6 | None | Thermal conductive sheet | 14.1 |
| | | 1 mm | |
| Example 7 | Thermal | Thermal conductive sheet | 14.7 |
| | conductive | 0.5 mm | |
| | sheet | | |
| | 0.5 mm | | |
| Example 8 | Thermal | Thermal conductive paste | 14.5 |
| | conductive | 0.5 mm (coating | |
| | paste | thickness) | |
| | 0.5 mm (coating | | |
| | thickness) | | |

### Example 9

A p-type thermoelectric conversion material composed of a Ca_{2.7}Bi_{0.3}Co₄O₉ sintered body having a rectangular column shape with a cross section of 7.0 mm×3.5 mm and a height of 13 mm, and an n-type thermoelectric conversion material composed of a CaMn_{0.98}Mo_{0.02}O₃ sintered body having a rectangular column shape with a cross section of 7.0 mm×3.5 mm and a height of 13 mm were connected to a silver plate (electrode) having a size of 7.1 mm×7.1 mm and a thickness of 0.1 mm, thereby producing a thermoelectric conversion element comprising a pair of a p-type thermoelectric conversion material and an n-type thermoelectric conversion material.

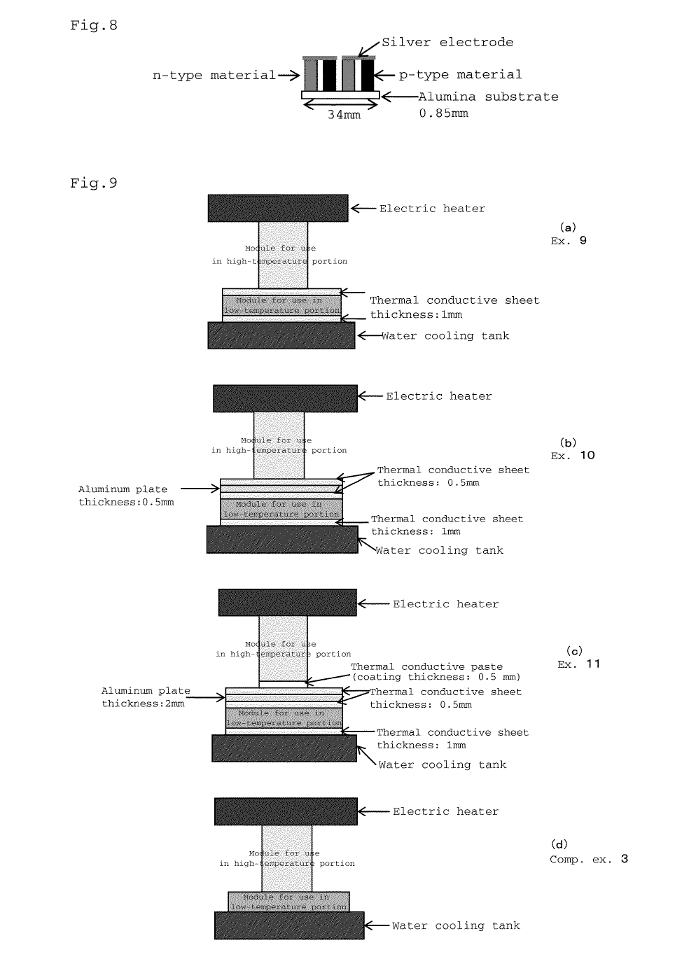

Using an alumina plate having a size of 34 mm×34 mm and a thickness of 0.85 mm as a substrate, the above-described thermoelectric conversion elements were bonded to the substrate in such a manner that an unconnected end of the p-type thermoelectric conversion material of the thermoelectric conversion element was connected to an unconnected end of the n-type thermoelectric conversion material of another thermoelectric conversion material, thereby producing a thermoelectric power generation module in which 16 pairs of thermoelectric conversion elements were connected in series. Silver paste was used as a binder. The thus-obtained module was used as a module for use in a high-temperature portion. FIG. 8 shows a schematic diagram of the module for use in a high-temperature portion obtained by this process.

Using a module having the same structure as the module for use in a low-temperature portion produced in Example 1, the aluminum substrate surface of the above-described module for use in a high-temperature portion was placed on the aluminum substrate surface of the module for use in a low-temperature portion via a thermal conductive sheet (tradename: λ GEL COH4000) (manufactured by Taika Corporation) (size: 64.5 mm×64.5 mm, thickness: 1 mm), which comprises silicone as a main component and a thermally conductive filler as an additive, thereby producing a stacked thermoelectric conversion module. Further, an aluminum cooling plate of an aluminum water cooling tank was contacted with the copper substrate surface of the module for use in a low-temperature portion in the stacked module via the same thermal conductive sheet. The alumina substrate surface of the module for use in a high-temperature portion of the stacked thermoelectric conversion module was heated with an electric heater to 800° C., and the copper substrate surface of the module for use in a low-temperature portion was cooled by flowing 20° C. water into the water cooling tank, so that thermoelectric power generation was performed. FIG. 9(a) shows the schematic structure of the stacked thermoelectric conversion module.

The module for use in a high-temperature portion and the module for use in a low-temperature portion were connected in series. The thermoelectric power generated in the above method was measured while varying the external resistance using an electronic load device. Table 3 shows the maximum output values in each example.

### Example 10

A stacked thermoelectric conversion module was produced in the same manner as in Example 9 except that, in the stacked thermoelectric conversion module produced in Example 9, a laminate comprising a 0.5-mm-thick aluminum plate sandwiched between two thermal conductive sheets (tradename: λ GEL COH4000) (manufactured by Taika Corporation) (size: 64.5 mm×64.5 mm, thickness: 0.5 mm), which comprises silicone as a main component and a thermally conductive filler as an additive, was used instead of the thermal conductive sheet disposed in the connecting area between the module for use in a high-temperature portion and the module for use in a low-temperature portion.

Using this stacked thermoelectric conversion module, thermoelectric power generation was performed in the same manner as in Example 9. FIG. 9(b) shows the schematic structure of the stacked thermoelectric conversion module. Table 3 shows the maximum output values measured in the same manner as in Example 9.

### Example 11

A stacked thermoelectric conversion module was produced in the same manner as in Example 9 except that, in the stacked thermoelectric conversion module produced in Example 9, a laminate formed by applying a commercially available silicone paste (tradename: SH 340 COMPOUND; manufactured by Dow Corning Toray Co., Ltd.) to both surfaces of a 2-mm-thick aluminum plate in such a manner that each surface had a coating of 0.5 mm in thickness was used instead of the thermal conductive sheet disposed in the connecting area between the module for use in a high-temperature portion and the module for use in a low-temperature portion.

Using this stacked thermoelectric conversion module, thermoelectric power generation was performed in the same manner as in Example 9. FIG. 9(c) shows the schematic structure of the stacked thermoelectric conversion module. Table 3 shows the maximum output values measured in the same manner as in Example 9.

### Comparative Example 3

A stacked thermoelectric conversion module was produced using the same module for use in a high-temperature portion and the same module for use in a low-temperature portion as those used in Example 9, wherein the module for use in a high-temperature portion and the module for use in a low-temperature portion were directly contacted without disposing a heat-transfer material therebetween, and the copper substrate surface of the module for use in a low-temperature portion and the aluminum cooling plate of an aluminum water cooling tank were directly contacted without disposing a heat-transfer material therebetween.

Using this stacked thermoelectric conversion module, thermoelectric power generation was performed in the same manner as in Example 9. FIG. 9(d) shows the schematic structure of the stacked thermoelectric conversion module. Table 3 shows the maximum output values measured in the same manner as in Example 9.

TABLE 3

| | | Heat-transfer | |
|---|---|---|---|
| | Heat-transfer | material between | |
| | material between | material between | |
| | modules | cooling member | |
| | Thickness (mm) | Thickness (mm) | Output (W) |
| Comparative | None | None | 6.5 |
| Example 3 | | | |
| Example 9 | Thermal conductive | Thermal conductive | 7.8 |
| | sheet 1 mm | sheet 1 mm | |
| Example 10 | Thermal conductive | Thermal conductive | 8.9 |
| | sheet 0.5 mm/ | sheet 1 mm | |
| | Aluminum 0.5 mm/ | | |
| | Thermal conductive | | |
| | sheet 0.5 mm | | |
| Example 11 | Thermal conductive | Thermal conductive | 8.7 |
| | paste 0.5 mm/ | sheet 1 mm | |
| | Aluminum 2 mm/ | | |
| | Thermal conductive | | |
| | paste 0.5 mm | | |

Production Examples and Test Examples of a silicon-based alloy are disclosed below as Reference Examples 1 to 37. The silicon-based alloy was used as an n-type thermoelectric conversion material among the thermoelectric conversion materials used for the module for use in a high-temperature portion in the stacked thermoelectric conversion module of the present invention, and represented by the formula: Mn₃₋ₓM¹ₓSi_{y}Al_{z}M²ₐ, wherein M¹ is at least one element selected from the group consisting of Ti, V, Cr, Fe, Co, Ni, and Cu; and M² is at least one element selected from the group consisting of B, P, Ga, Ge, Sn, and Bi; where 0≦x≦3.0, 3.5≦y≦4.5, 2.5≦z≦3.5, and 0≦a≦1.

### Reference Example 1

Using manganese (Mn) as a source of Mn, silicon (Si) as a source of Si, and aluminum (Al) as a source of Al, the raw materials were mixed in such a manner that Mn:Si:Al (elemental ratio)=3.0:4.0:3.0. The raw material mixture was melted by an arc-melting method under an argon atmosphere; the melt was then fully mixed, and cooled to room temperature to obtain an alloy composed of the metal components mentioned above.

Subsequently, the resulting alloy was subjected to ball mill pulverization using an agate vessel and an agate ball. Thereafter, the resulting powder was pressed into a disc shape having a diameter of 40 mm and a thickness of 4.5 mm. The result was placed in a carbon mold, heated to 850° C. by applying a pulsed direct current of about 2700 A (pulse width: 2.5 milliseconds, frequency: 29 Hz), and maintained at that temperature for 15 minutes. After performing electric current sintering, the application of current and pressure was stopped, and the result was allowed to cool to obtain a sintered body.

### Reference Examples 2 to 37

The sintered bodies having the compositions shown in Table 4 were obtained in the same manner as in Reference Example 1, except that the types and proportions of the raw materials were altered. As the raw materials, elementary metals of each material were used.

### Test Example

The Seebeck coefficient, electric resistivity, thermal conductivity, and dimensionless figure of merit of each sintered body of Reference Examples 1 to 37 were obtained by the methods described below.

Hereunder, the method for obtaining the physical-property values to evaluate the thermoelectrical characteristics is explained. The Seebeck coefficient and electric resistivity were measured in air, and the thermal conductivity was measured in a vacuum.

Seebeck Coefficient

A sample was formed into a rectangular column having a cross-section of about 3 to 5 mm square and a length of about 3 to 8 mm. An R-type thermocouple (platinum-platinum rhodium) was connected to each end of the sample using a silver paste. The sample was placed in a tubular electric furnace, heated to 100 to 700° C., and given a temperature difference by applying room temperature air using an air pump to one of the ends provided with the thermocouple. Thereafter, the thermoelectromotive force generated between both ends of the sample was measured using the platinum wire of the thermocouple. The Seebeck coefficient was calculated based on the thermoelectromotive force and the temperature difference between the ends of the sample.

Electric Resistivity

A sample was formed into a rectangular column having a cross-section of about 3 mm to 5 mm square and a length of about 3 mm to 8 mm. Using a silver paste and a platinum wire, electric current terminals were provided at both ends, and voltage terminals were provided at the side surfaces. The electric resistivity was measured by a DC four-terminal method.

Thermal Conductivity

A sample was formed into a shape having a width of about 5 mm, a length of about 8 mm, and a thickness of about 1.5 mm. The thermal diffusivity and specific heat were measured by a laser flash method. The thermal conductivity was calculated by multiplying the resulting values by density measured using Archimedes' method.

Table 1 below shows the Seebeck coefficient (μU/K), electric resistivity (mΩ·cm), thermal conductivity (W/m·K²), and dimensionless figure of merit at 500° C. for each alloy obtained in each Example.

TABLE 4

| | | | | | Dimen- |
|---|---|---|---|---|---|
| | | | | | sion- |
| | | | | | less |
| | | | | | figure |
| | | Seebeck | Electric | Thermal | of merit |
| | | coefficient | resistivity | conductivity | at |
| | | at 500° C. | at 500° C. | at 500° C. | 500° C. |
| No. | Composition | (μV/K) | (mQ · cm) | (W/m · K²) | ZT |
| 1 | Mn₃Si₄Al₃ | −92.9 | 0.91 | 3.6 | 0.20 |
| 2 | Mn_{2.8}Co_{0.2}Si₄Al₃ | −48.4 | 0.99 | 3.4 | 0.05 |
| 3 | Mn_{2.8}Fe_{0.2}Si₄Al₃ | −41.8 | 0.80 | 3.5 | 0.05 |
| 4 | Mn_{2.8}Ni_{0.2}Si₄Al₃ | −10.1 | 0.60 | 3.3 | 0.004 |
| 5 | Mn₃Si_{4.5}Al₃ | −50.1 | 0.93 | 3.6 | 0.06 |
| 6 | Mn₃Si_{4.2}Al_{2.8} | −72.5 | 0.84 | 3.6 | 0.13 |
| 7 | Mn₃Si_{3.8}Al_{3.2} | −83.9 | 0.91 | 3.7 | 0.16 |
| 8 | Mn₃Si_{3.5}Al₃ | −84.1 | 1.0 | 3.2 | 0.17 |
| 10 | Mn₃Si_{3.9}Al₃ | −83.1 | 1.0 | 3.2 | 0.17 |
| 11 | Mn₃Si_{3.8}Al₃P_{0.2} | −66.2 | 0.7 | 3.0 | 0.16 |
| 12 | Mn₃Si₄Al₂P | −40.5 | 0.6 | 3.1 | 0.07 |
| 13 | Mn₃Si_{3.8}Al₃B_{0.2} | −82.3 | 0.8 | 2.9 | 0.23 |
| 14 | Mn₃Si₄Al₂B | −79.4 | 0.7 | 3.3 | 0.21 |
| 15 | Mn₃Si_{3.8}Al₃Ga_{0.2} | −80.1 | 0.9 | 3.0 | 0.18 |
| 16 | Mn₃Si₄Al₂Ga | −67.8 | 1.0 | 2.7 | 0.13 |
| 17 | Mn₃Si_{3.8}Al₃Ge_{0.2} | −54.3 | 0.7 | 3.5 | 0.09 |
| 18 | Mn₃Si₄Al₂Ge | −32.7 | 0.5 | 3.2 | 0.05 |
| 19 | Mn₃Si_{3.8}Al₃Sn_{0.2} | −68.5 | 0.6 | 3.7 | 0.16 |
| 20 | Mn₃Si₄Al₂Sn | −32.1 | 0.5 | 2.8 | 0.06 |
| 21 | Mn₃Si_{3.8}Al₃Bi_{0.2} | −72.9 | 0.8 | 3.2 | 0.16 |
| 22 | Mn₃Si₄Al₂Bi | −49.7 | 0.7 | 3.4 | 0.08 |
| 23 | Mn₃Si₄Al₃Bi_{0.02} | −82.8 | 0.9 | 3.3 | 0.18 |
| 24 | Mn_{2.9}Ti_{0.1}Si₄Al₃ | −92.1 | 0.9 | 3.5 | 0.21 |
| 25 | Ti₃Si₄Al₃ | −67.2 | 1.0 | 2.7 | 0.13 |
| 26 | Mn_{2.9}V_{0.1}Si₄Al₃ | −87.2 | 0.9 | 3.4 | 0.19 |
| 27 | V₃Si₄Al₃ | −88.3 | 1.0 | 3.8 | 0.16 |
| 28 | Mn_{2.9}Cr_{0.1}Si₄Al₃ | −70.5 | 0.8 | 3.2 | 0.15 |
| 29 | Cr₃Si₄Al₃ | −91.3 | 1.0 | 3.1 | 0.21 |
| 30 | Mn_{2.9}Fe_{0.1}Si₄Al₃ | −90.1 | 0.7 | 2.9 | 0.31 |
| 31 | Fe₃Si₄Al₃ | −89.5 | 1.0 | 3.0 | 0.21 |
| 32 | Mn_{2.9}Co_{0.1}Si₄Al₃ | −76.3 | 0.8 | 3.2 | 0.18 |
| 33 | Co₃Si₄Al₃ | −67.8 | 1.0 | 2.9 | 0.12 |
| 34 | Mn_{2.9}Ni_{0.1}Si₄Al₃ | −72.3 | 0.9 | 3.1 | 0.14 |
| 35 | Ni₃Si₄Al₃ | −65.5 | 1.0 | 3.2 | 0.10 |
| 36 | Mn_{2.9}Cu_{0.1}Si₄Al₃ | −82.1 | 0.9 | 3.3 | 0.18 |
| 37 | Cu₃Si₄Al₃ | −60.2 | 0.7 | 3.6 | 0.11 |

As is evident from the results described above, the sintered alloy bodies obtained in Reference Examples 1 to 37 had a negative Seebeck coefficient and a low electric resistivity at 500° C., therefore exhibiting an excellent capability as an n-type thermoelectric conversion material.

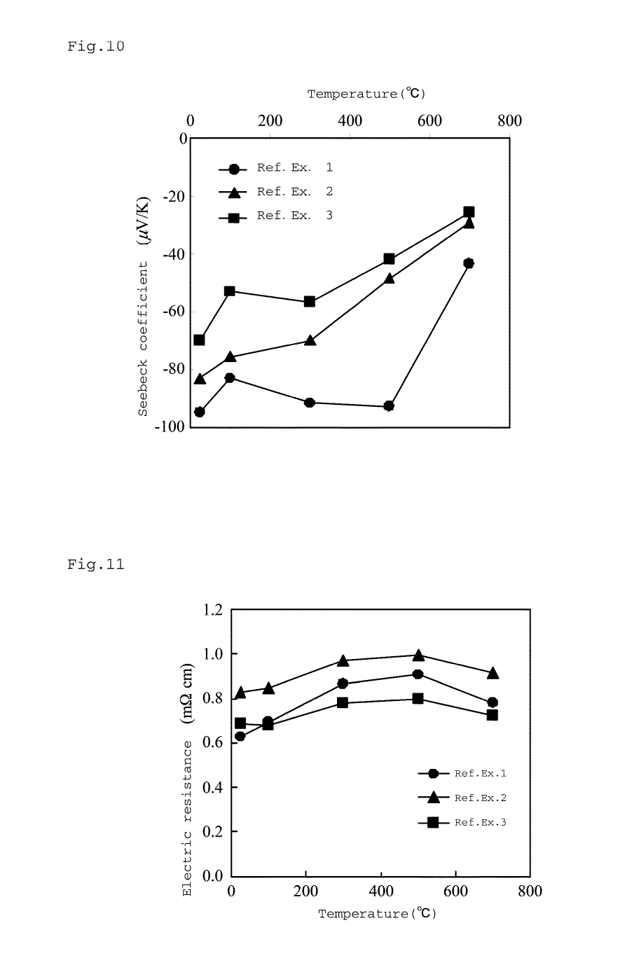

FIG. 10 is a graph showing the temperature dependency of the Seebeck coefficients of the sintered alloy bodies obtained in Reference Examples 1 to 3 measured in air at 25 to 700° C. FIG. 11 is a graph showing the temperature dependency of the electric resistivity of the sintered alloy bodies measured in air at 25 to 700° C.

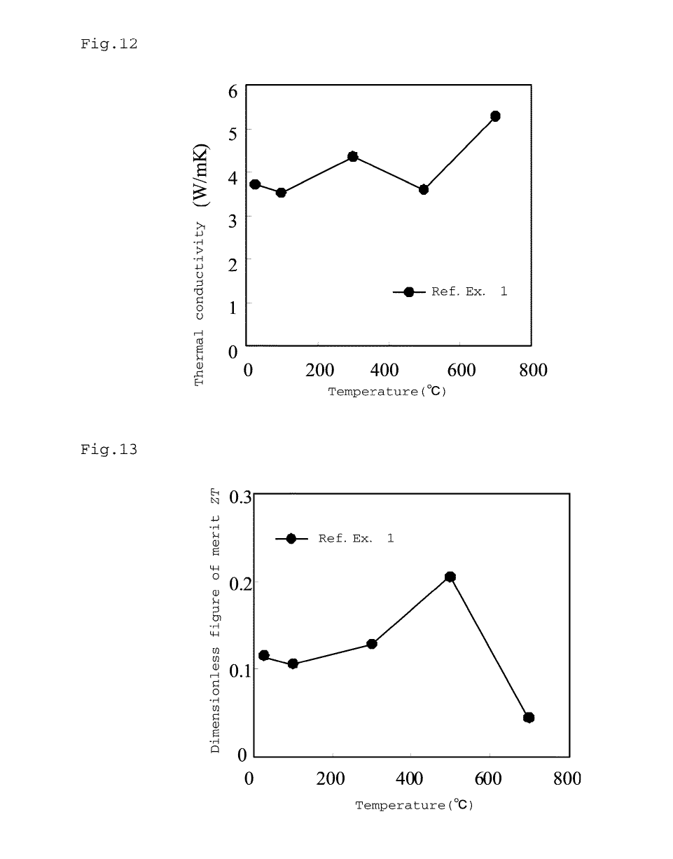

FIG. 12 shows the temperature dependency of the thermal conductivity of the sintered alloy body obtained in Reference Example 1 measured in air at 25 to 700° C. FIG. 13 shows the temperature dependency of the dimensionless figure of merit (ZT) of the sintered alloy body measured in air at 25 to 700° C.

As is evident from the results described above, the sintered alloy bodies obtained in Reference Examples 1 to 3 had a negative Seebeck coefficient in the temperature region of 25 to 700° C. They were confirmed to be n-type thermoelectric conversion materials in which the hot side has a high electric potential. These alloys had a high absolute value for the Seebeck coefficient in the temperature region of 600° C. or below, and, in particular, at about 300 to 500° C.

Furthermore, because no deterioration in performance due to oxidation was observed even in the measurement conducted in air, it is revealed that the metal material of the present invention has an excellent oxidation resistance. Furthermore, the sintered alloy bodies obtained in Reference Examples 1 to 3 had an electric resistivity (ρ) of less than 1 mΩ·cm in the temperature region of 25 to 700° C., revealing extremely excellent electrical conductivity. Accordingly, the sintered alloy bodies obtained in the Reference Examples described above can be efficiently used as an n-type thermoelectric conversion material in air in the temperature region up to about 600° C., and, in particular, at about 300 to 500° C.

1. A stacked thermoelectric conversion module having a structure wherein a module for use in a high-temperature portion and a module for use in a low-temperature portion are stacked:
the module for use in a high-temperature portion being a thermoelectric conversion module comprising a metal oxide as each thermoelectric conversion material or a thermoelectric conversion module comprising a silicon-based alloy as each thermoelectric conversion material;
the module for use in a low-temperature portion being a thermoelectric conversion module comprising a bismuth-tellurium-based alloy as each thermoelectric conversion material; and
a flexible heat-transfer material being disposed between the module for use in a high-temperature portion and the module for use in a low-temperature portion.

2. A stacked thermoelectric conversion module having a structure wherein a module for use in a high-temperature portion and a module for use in a low-temperature portion are stacked:
the module for use in a high-temperature portion being a thermoelectric conversion module comprising a metal oxide as each thermoelectric conversion material or a thermoelectric conversion module comprising a silicon-based alloy as each thermoelectric conversion material;
the module for use in a low-temperature portion being a thermoelectric conversion module comprising a bismuth-tellurium-based alloy as each thermoelectric conversion material,
the stacked thermoelectric conversion module further comprising a cooling member disposed at a cooling surface side of the module for use in a low-temperature portion; and
a flexible heat-transfer material being disposed between the module for use in a low-temperature portion and the cooling member.

3. The stacked thermoelectric conversion module according to claim 1, wherein a cooling member is disposed at the cooling surface side of the module for use in a low-temperature portion, and a flexible heat-transfer material is disposed between the module for use in a low-temperature portion and the cooling member.

4. The stacked thermoelectric conversion module according to claim 1, wherein, in addition to the flexible heat-transfer material, a metal plate is disposed between the module for use in a high-temperature portion and the module for use in a low-temperature portion.

5. The stacked thermoelectric conversion module according to claim 1,
the module for use in a high-temperature portion and the module for use in a low-temperature portion each comprising a plurality of thermoelectric conversion elements in which one end of a p-type thermoelectric conversion material and one end of an n-type thermoelectric conversion material are electrically connected, and
the plurality of thermoelectric conversion elements being connected in series by electrically connecting an unconnected end of a p-type thermoelectric conversion material of one thermoelectric conversion element to an unconnected end of an n-type thermoelectric conversion material of another thermoelectric conversion element,
wherein
(i) the thermoelectric conversion element forming a module for use in a high-temperature portion comprises a p-type thermoelectric conversion material of a complex oxide represented by the formula: CaₐM_{b}Co₄O_{c}, wherein M is one or more elements selected from the group consisting of Na, K, Li, Ti, V, Cr, Mn, Fe, Ni, Cu, Zn, Pb, Sr, Ba, Al, Bi, Y and lanthanide, where 2.2≦a≦3.6; 0≦b≦0.8; 8≦c≦10; and an n-type thermoelectric conversion material of a complex oxide represented by the formula: Ca₁₋ₓM¹ₓMn_{1-y}M²_{y}O_{z}, wherein M¹ is at least one element selected from the group consisting of Ce, Pr, Nd, Sm, Eu, Gd, Yb, Dy, Ho, Er, Tm, Tb, Lu, Sr, Ba, Al, Bi, Y and La; M² is at least one element selected from the group consisting of Ta, Nb, W and Mo; and x, y and z are in the ranges of 0≦x≦0.5, 0≦y≦0.2, 2.7≦z≦3.3; or
the thermoelectric conversion element forming a module for use in a high-temperature portion comprises a p-type thermoelectric conversion material of a silicon-based alloy represented by the formula: Mn₁₋ₓM^{a}ₓSi_{1.6-1.8}, wherein M^{a} is one or more elements selected from the group consisting of Ti, V, Cr, Fe, Ni and Cu; 0≦x≦0.5; and an n-type thermoelectric conversion material of a silicon-based alloy represented by the formula:
Mn₃₋ₓM¹ₓSi_{y}Al_{z}M²ₐ, wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1; and
(ii) the thermoelectric conversion element forming a module for use in a low-temperature portion comprises a p-type thermoelectric conversion material of a bismuth-tellurium-based alloy represented by the formula: Bi₂₋ₓSbₓTe₃, wherein 0.5≦x≦1.8; and an n-type thermoelectric conversion material of a bismuth-tellurium-based alloy represented by the formula: Bi₂Te₃₋ₓSeₓ, wherein 0.01≦x≦0.3.

6. The stacked thermoelectric conversion module according to claim 1, wherein the flexible heat-transfer material is a resin-based paste material or a resin-based sheet material each having a thermal resistivity of approximately 1 mK/W or less.

7. A stacked thermoelectric conversion module according to claim 4, wherein the metal plate is an aluminum plate.
